(19) United States
(12) Patent Application Publication
(10) Pub. No.: US 2022/0406749 A1
(43) Pub. Date: Dec. 22, 2022

(54) ELECTRICAL CONNECTION METHOD FOR ELECTRONIC ELEMENT, AND RELATED APPARATUS THEREOF

(71) Applicant: BOE Technology Group Co., Ltd., Beijing (CN)

(72) Inventors: Zhanfeng CAO, Beijing (CN); Jiushi WANG, Beijing (CN); Ke WANG, Beijing (CN); Guocai ZHANG, Beijing (CN); Junwei YAN, Beijing (CN); Yingwei LIU, Beijing (CN); Haitao HUANG, Beijing (CN); Guangcai YUAN, Beijing (CN)

(21) Appl. No.: 17/638,703

(22) PCT Filed: Feb. 28, 2020
(86) PCT No.: PCT/CN2020/077302

§ 371 Date: Feb. 25, 2022

(51) Int. Cl. H01L 23/00; H01L 33/62; H01L 25/075; H01L 25/16

(52) U.S. Cl. CPC H01L 24/81; H01L 24/13; H01L 33/62; H01L 25/0753; H01L 24/16; H01L 25/167; H01L 2224/81009; H01L 2224/1141; H01L 2224/13083; H01L 2224/13111; H01L 2224/81815; H01L 2224/13147; H01L 2224/1318; H01L 2224/13166; H01L 2924/0132; H01L 2224/13179; H01L 2224/1132; H01L 2224/812; H01L 2933/0066; H01L 2224/16145; H01L 2224/16225; H01L 2924/12041; G02F 1/133603

(57) ABSTRACT

Disclosed are an electrical connection method for an electronic element, and a backlight module, a display panel, and a display apparatus which include an electronic element to which the electrical connection method is applied. The electrical connection method comprises: providing a driving back plane, wherein the driving back plane comprises multiple contact electrodes; forming an anti-oxidation protection film on the contact electrodes; coating a position of the anti-oxidation protection film corresponding to each contact electrode with a binding material; and transferring multiple electronic elements to the positions of the corresponding contact electrodes, binding each electronic element to the corresponding contact electrode, and removing the anti-oxidation protection film at the position of each contact electrode before completing the binding of each electronic element to the corresponding contact electrode.

### FIELD

The present disclosure relates to the field of display, in particular to an electrical connection method of electronic element and related apparatus thereof.

### BACKGROUND

With the development of electronic technology, multiple functions can be achieved through electronic components. For example, a function of providing a light source or display can be achieved through a Mini-Light Emitting Diode (Mini-LED).

In order to control the electronic components to achieve corresponding functions, such as controlling the light emission of the Mini-LED, the electronic components need to be bound to a driving backplane through a binding material. Since contact electrodes on the driving backplane are prone to being oxidized, it will cause poor electrical contact between the contact electrodes and the binding material. Therefore, before binding the electronic components with the contact electrodes, oxides on the surfaces of the contact electrodes need to be removed.

### SUMMARY

An electrical connection method of electronic components provided by embodiments of the present disclosure includes:
providing a driving backplane including a plurality of contact electrodes;
forming an anti-oxidation protective film on the contact electrodes;
coating the anti-oxidation protective film at positions corresponding to the contact electrodes with a binding material;
transferring a plurality of electronic components to positions of the contact electrodes; and
binding the electronic components each with a respective one of the contact electrodes;
wherein before completing the binding of the electronic components each to the respective one of the contact electrodes, the anti-oxidation protective film at the positions of the contact electrodes are removed.

Optionally, in the embodiments of the present disclosure, the forming the anti-oxidation protective film on the contact electrodes, includes: putting the driving backplane in an anti-oxidation protective solution, and soaking for 30-90 s.

Optionally, in the embodiments of the present disclosure, the putting the driving backplane in the anti-oxidation protective solution, includes: putting the driving backplane in a. solution of benzotriazole.

Optionally, in the embodiments of the present disclosure, the coating the anti-oxidation protective film at positions corresponding to the contact electrodes with the binding material, includes: coating the anti-oxidation protective film with tin paste.

Optionally, in the embodiments of the present disclosure, the binding the electronic components each with the respective one of the contact electrodes, includes: binding the electronic components with the respective one of the contact electrodes by adopting a reflow soldering process.

Optionally, in the embodiments of the present disclosure, the binding material is doped with a reactant for removing the anti-oxidation protective film; and the binding the electronic components each with a respective one of the contact electrodes, includes:
volatilizing a product of the reactant and the anti-oxidation protective film, and an excess reactant, in the process of binding the electronic components each with the respective one of the contact electrodes.

Optionally, in the embodiments of the present disclosure, the reactant includes rosin resin or isophthalic acid.

Optionally, in the embodiments of the present disclosure, after forming the anti-oxidation protective film on the contact electrodes, within a set time before coating the anti-oxidation protective film at positions corresponding to the contact electrodes with the binding material, the method further includes:
putting the driving backplane after forming the anti-oxidation protective film in a reactant used for removing the anti-oxidation protective film, and soaking for 60-120 s.

Optionally, in the embodiments of the present disclosure, the reactant includes isophthalic acid, ethyl alcohol or dilute acid.

Correspondingly, the embodiments of the present disclosure further provide a backlight module, including: a driving backplane, and a plurality of electronic components arranged above the driving backplane, and the electronic components are connected with contact electrodes in the driving backplane in a binding mode by adopting the above electrical connection method; the electronic components include a Mini-LED, and the backlight module further includes an optical film layer arranged on a light emitting side of the Mini-LED.

Correspondingly, the embodiments of the present disclosure further provide a display panel, including: a driving backplane, and a plurality of electronic components arranged above the driving backplane, the electronic components are connected with contact electrodes in the driving backplane in a binding mode by adopting the above electrical connection method; and the electronic components include a Mini-LED.

Correspondingly, the embodiments of the present disclosure further provide a display apparatus, including: the above backlight module and a liquid crystal display panel arranged on a light emitting side of the backlight module; or the above display panel,

### BRIEF DESCRIPTION OF THE DRAWINGS

FIG. 1 is a flow chart of an electrical connection method of electronic components provided by an embodiment of the present disclosure.

FIG. 2 is a schematic structural diagram of a driving backplane provided by an embodiment of the present disclosure.

FIG. 3 is a schematic structural diagram of an anti-oxidation protective film formed in an embodiment of the present disclosure.

FIG. 4 is a schematic structural diagram of a binding material coated in an embodiment of the present disclosure.

FIG. 5 is a schematic structural diagram of a driving backplane after transferring electronic components in an embodiment of the present disclosure.

FIG. 6 is a schematic structural diagram of a driving backplane after being bound with electronic components in an embodiment of the present disclosure.

### DETAILED DESCRIPTION OF THE EMBODIMENTS

In view of the problem that contact electrodes on a driving backplane are prone to being oxidized, which causes poor contact between the contact electrodes and a binding material, embodiments of the present disclosure provide an electrical connection method of electronic element and related apparatus thereof.

The implementations of the electrical connection method of electronic element and related apparatus thereof provided by the embodiments of the present disclosure will he described in detail below with reference to the accompanying drawings. The thickness and shape of each film layer in the accompanying drawings do not reflect the true ratio, and the purpose is only to illustrate the content of the present disclosure schematically.

A nickel-gold process can be adopted to remove oxides on surfaces of contact electrodes and add a layer of highly anti-oxidative alloy material. For example a 2-3 μm nickel-gold layer can be deposited to protect the contact electrodes. However, an inventor found. that due to the problem of insufficient process control accuracy in the nickel-gold process, it is inevitable that the nickel-gold layer falls off and other defects. Moreover, the nickel-gold process belongs to a traditional electrochemical process, which has certain pollution.

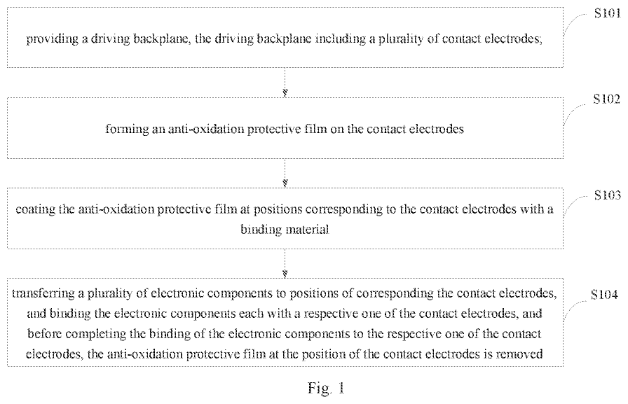

The embodiments of the present disclosure provide an electrical connection method of electronic components, as shown in FIG. 1, including:

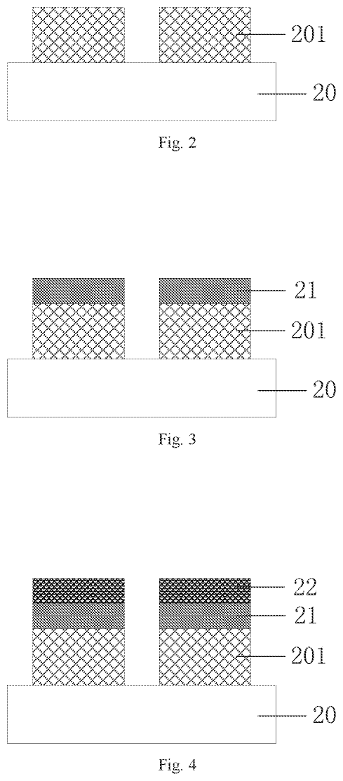

S101, referring to FIG. 2, providing a driving backplane 20, the driving backplane 20 including a plurality of contact electrodes 201;

S102, referring to FIG. 3, forming an anti-oxidation protective film 21 on the contact electrodes 201;

S103, referring to FIG. 4, coating the anti-oxidation protective film 21 at positions corresponding to the contact electrodes 201 with a binding material 22;

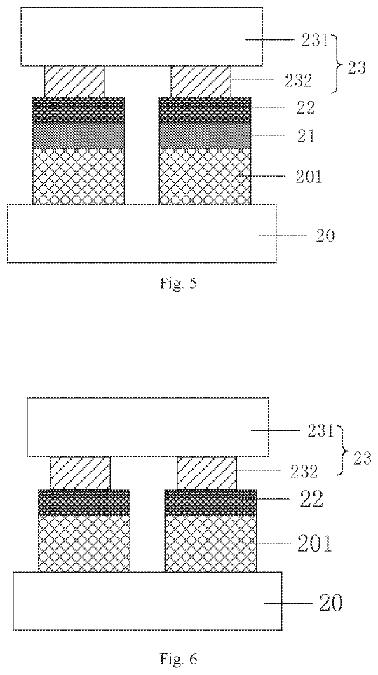

S104, referring to FIG. 5, transferring a plurality of electronic components 23 to positions of corresponding the contact electrodes 201, and binding the electronic components 23 each with a respective one of the contact electrodes 210, and before completing the binding of the electronic components 23 to the respective one of the contact electrodes 201, the anti-oxidation protective film 21 at the position of the contact electrodes 201 is removed, so as to obtain a structure shown in FIG. 6.

According to the electrical connection method of the electronic components provided by the embodiments of the present disclosure, the anti-oxidation protective film is formed on the contact electrodes, so that the contact electrodes can be prevented from being oxidized for a long time, it is ensured that the contact electrodes can be well connected with the binding material, the nickel-gold process can be omitted, and the process is simplified. Accordingly, the electronic components provided by the embodiments of the present disclosure may be Mini-LEDs, and also may be electronic components of other electrode pins, which are not limited here. Specifically, the Mini-LEDs may include a Micro Light Emitting Diode (Micro LED) or a mini Light Emitting Diode (mini-LED), etc,

Referring to FIG. 2, in above step S101, since Cuprum (Cu) has a good conductivity and a low cost, the contact electrodes 201 may be mainly made of Cu materials, and in order to increase the adhesion of the contact electrodes 201, the contact electrodes 201 may further include an adhesive layer, which may include Molybdenum (Mo), Titanium (Ti), a Molybdenum-Titanium alloy (MoTi) or a Molybdenum-Niobium alloy (MoNb), etc. That is to say, the contact electrodes 201 include the adhesive layer and a laminated structure of a Cu layer located on a substrate side, facing away from the driving backplane, of the adhesive layer. In practical application, the driving backplane 20 may further include a drive circuit connected with the contact electrodes 201, and the drive circuit can control the electronic components to achieve the corresponding functions by applying drive signals to the contact electrodes 201.

Referring to FIG. 5, the above electronic components may generally include an epitaxial structure 231 and a positive and negative electrode 232. In above step S104, the electronic components 23 are transferred to the corresponding contact electrodes 201, and the positive and negative electrode 232 needs to be aligned and in contact with the corresponding contact electrode 201.

Accordingly, the above binding method provided by the embodiments of the present disclosure, in above step S102, may include: putting the driving backplane in an anti-oxidation protective solution, and soaked for 30-90 s.

In order to make the contact electrodes and the binding material be able to connect well, the above anti-oxidation protective solution may be adopted to react with oxides on surfaces of the contact electrodes, so as to remove the oxides on the surfaces of the contact electrodes, it is ensured that the contact electrodes can be well connected with the binding material, and the anti-oxidation protective film is formed to protect the contact electrodes. As shown in FIG. 3, since the anti-oxidation protective film 21 is obtained by the reaction of the anti-oxidation protective solution and the oxides, the anti-oxidation protective film 21 is only formed on the surfaces of the contact electrodes 201.

In an optional implementation, the driving backplane may be put in a container filled with the anti-oxidation protective solution, devices and process for making the anti-oxidation protective film are simple, and the making cost is low The driving backplane is soaked in the anti-oxidation protective solution for 30-90 seconds, so that an anti-oxidation protective film with a thickness of 1000-3000 Å may be formed.

Moreover, in the above binding method provided by the embodiments of the present disclosure, above step S102, the driving backplane is put in the anti-oxidation protective solution includes: putting the driving backplane in a solution of benzotriazole BTAH.

Accordingly, a molecular formula of the benzotriazole BTAH is C₆H₅N₃, and a structural formula is:

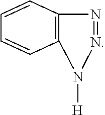

A complex reaction may be performed between the benzotriazole BTAH material and the oxides on the surfaces of the contact electrodes. Taking that the material of the contact electrodes is Cu as an example, since the oxidation of Cu is related to factors such as temperature, ambient gas and humidity, the surface of Cu may be oxidized to cuprous oxide under high temperature, and cuprous oxide is gradually oxidized to cupric oxide in humid air. In the actual process of making the contact electrodes, the temperature is high, so cuprous oxide may be formed on the surfaces of the contact electrodes. In the actual process, the humidity in environment of a reaction chamber may be controlled, and the cuprous oxide may be hardly further oxidized to cupric oxide. Therefore, main components of the oxide on the surfaces of the contact electrodes are cuprous oxide.

Accordingly, the complex reaction may be performed between the benzotriazole BTAH material and Cu₂O to form a complex Cu-BTA of Cu₂O, so that the oxides on the surfaces of the contact electrodes are removed, and the formed complex can protect the contact electrodes. A specific reaction formula is as follows:

2BTAH+Cu₂O→2Cu-BTA+H₂O.

It can be seen from the above reaction formula that H₂O is generated after the complex reaction, the generated water may be removed by washing and drying to prevent the generated water from adversely affecting the contact electrodes.

In addition, because BTAH-based materials have 2 lone pairs of electrons per N atom, the overall anti-oxidation protective film is slightly negative, while the contact electrodes with the surfaces of Cu₂O are positive. Therefore, the anti-oxidation protective film and the contact electrodes with the surfaces of Cu₂O are electrostatically adsorbed, and the anti-oxidation protective film may be adsorbed to the surfaces of the contact electrodes.

In an optional implementation, in addition to the benzotriazole BTAH, other materials may also be adopted to make the above anti-oxidation protective film. For example, other ink materials may be adopted, and the material of the anti-oxidation protective film is not limited here.

In the embodiments of the present disclosure, the performance of the anti-oxidation protective film formed on the contact electrodess is good, the contact electrodes may not be oxidized for a long time (generally up to three months). Therefore, before completing the binding of the electronic components to the contact electrodes, sufficient operation time may be reserved for the coating process and the binding process of the binding material to increase the flexibility of mass production.

In an optional implementation, in the above binding method provided by the embodiments of the present disclosure, above step S103, may include:
coating the anti-oxidation protective film with tin paste by adopting a silk-screen priming process or a high precision printing process. That is to say, the tin paste is adopted as the binding material. By adopting the silk-screen printing process or the high precision printing process, the tin paste may be accurately coat on the anti-oxidation protective film, and material waste is avoided.

In the practical application, in the above binding method provided by the embodiments of the present disclosure, in above step S104, binding the electronic components each with a respective one of the contact electrodes, includes:
binging the electronic components each with the respective one of the contact electrodes by adopting a reflow soldering process.

Accordingly, the plurality of electronic components each is transferred to the positions of the respective one of the contact electrodes, so that positive and negative electrodes 232 of the electronic components are in contact with the binding material at the corresponding position, and then the driving backplane is put in a device of the reflow soldering process. After heating air or nitrogen to a sufficiently high temperature, the air or nitrogen is blown to the driving backplane, the binding material may be melted when the temperature reaches more than 217°, and after the binding material is cooled, the binding between the electronic components and the binding material at the corresponding position can he achieved. The reflow soldering process is adopted, the temperature is easy to control, the oxidation of the contact electrodes can be avoided in the reflow soldering process, and the making cost is also relatively low.

In addition, after the above reflow soldering process, optical detection may further be performed on the driving backplane, so as to detect whether morphology of the binding material meets requirements.

In the practical application, in the above binding method provided by the embodiments of the present disclosure, different modes may be adopted to remove the anti-oxidation protective film.

In some embodiments of the present disclosure, the binding material is doped with a reactant used for removing the anti-oxidation protective film; and
the step that binding the electronic components each with the respective one of the contact electrodse, includes:
volatilizing a product of the reactant and the anti-oxidation protective film, and an excess reactant, in a process of binding the electronic components each with the respective one of the contact electrodes.

Since the binding material is doped with the reactant used for removing the anti-oxidation protective film, in above step S 103, after coating the binding material, the reactant starts to react with the anti-oxidation protective film. Referring to FIG. 5, in above step S104, when the electronic components 23 are transferred to the positions of the corresponding contact electrodes 201, the anti-oxidation protective film is partially removed. In the process of binding the electronic components 23 each with the respective one of the contact electrodes 201, since heating is needed in the reflow soldering process, the reaction between the reactant and the anti-oxidation protective film may be accelerated, and the reaction product and the excess reactant are volatilized. The removing process of the anti-oxidation protective film in the above embodiments is compatible with the binding process of the electronic components, and any other devices do not need to be added.

In some embodiments, the above reactant needs to have active groups to remove the anti-oxidation protective film. For example, the above reactant may be a material containing carboxylic acid (RCOOH), and a specific reaction formula for removing the anti-oxidation protective film may be:

Cu-BTA+nRCOOH→Cu+(RCOOH)n-BTA, and
since the anti-oxidation protective film is thin, and a boiling point and a flash point of BTA are low, about 150-200 degrees, while the temperature of the reflow soldering process is about 250 degrees, the anti-oxidation protective film, the reactant and the reaction product can be completely removed.

In the above binding method provided by the embodiments of the present disclosure, the above reactant, may include: rosin resin or isophthalic acid. The rosin resin and the isophthalic acid are both organic materials, and the organic materials are adopted as the reactant, which is easier to be mixed with the binding material.

In an optional implementation, the binding material generally may include a flux, and the flux can promote the binding process between a light-emitting diode chip and the contact electrodes by the binding material, so that the above reactant may be doped into the flux. In the reflow soldering process, the flux may also be volatilized along with the reactant.

The flux is a mixture which is usually made of rosin as a main component, and is an auxiliary material for ensuring the smooth progress of the welding process. Main raw materials are an organic solvent (commonly used are ethyl alcohol, propyl alcohol and butyl alcohol; acetone and toluene isobutyl ketone; and acetic ether and butyl acetate), rosin resin and its derivatives, a synthetic resin surfactant, an organic acid activator, a corrosion inhibitor, a cosolvent and a film-forming agent, etc., that is, the flux is a uniform and transparent mixed solution formed by dissolving various solid components in various liquids.

In other embodiments of the present disclosure, after step S102, within a set time before step S103, the method nay further include:
putting the driving backplane after forming the anti-oxidation protective film in the reactant used for removing the anti-oxidation protective film, and soaked for 60-120 s.

After forming the anti-oxidation protective film, the anti-oxidation protective film can protect the contact electrodes and prevent the contact electrodes from being oxidized. The anti-oxidation protective film is removed within the set time before coating the binding material. Due to short exposure time of the contact electrodes, an oxidation film firmed on the surfaces of the contact electrodes is thin, and the binding material is coated on the contact electrodes as soon as possible, which has little impact on the connection performance between the binding material and the contact electrodes. In an optional implementation, if the binding material is coated on the contact electrodes within 24 hours after removing the anti-oxidation protective film, the connection performance between the binding material and the contact electrodes will not be affected.

In an optional implementation, the driving backplane after forming the anti-oxidation protective film is put in the reactant and soaked for 60-120 s, the anti-oxidation protective film may be removed, the process devices are simple, and the cost is low The anti-oxidation protective film is soaked in the reactant for 60-120 s, it can be ensured that the anti-oxidation protective film can be completely removed.

In the above binding method provided by the embodiments of the present disclosure, the above reactant, may include: isophthalic acid, ethyl alcohol or dilute acid. The anti-oxidation protective film is soaked in the organic solvent (such as isophthalic acid) or a dilute acid solution, the anti-oxidation protective film can be easily removed, the process is simple, and the cost is low.

Taking dilute sulphuric acid as an example, a specific reaction formula for removing the anti-oxidation protective film may be:

Cu-BTA+H₂SO₄→CuSO₄+BTA+H₂.

It can be seen from the above reaction formula that after removing the anti-oxidation protective film, other substances may not be formed on the contact electrodes, and the anti-oxidation protective film can be completely removed.

Based on the same inventive concept, the embodiments of the present disclosure further provides a backlight module, including: a driving backplane, and a plurality of electronic components arranged above the driving backplane. The electronic components are connected with contact electrodes in the driving backplane in a binding mode by adopting the above electrical connection method;
the above each electronic component includes a Mini-LED; and
the above backlight module further includes an optical film layer located on a light emitting side of the Mini-LED.

In the above backlight module in the embodiments of the present disclosure, the Mini-LED is connected with the contact electrodes in the driving backplane in a binding mode by adopting the above electrical connection method, so that the connection performance between the Mini-LED and the contact electrodes is good. Optionally, in a light emitting direction of the Mini-LED, the optical film layer such as a diffuser sheet, a prism sheet, etc. may further be arranged. Therefore, the backlight module can provide light with good uniformity for a liquid crystal display panel.

Based on the same inventive concept, the embodiments of the present disclosure further provide a display panel, including: a driving backplane, and a plurality of electronic components located above the driving backplane. The electronic components are connected with contact electrodes in the driving backplane in a binding mode by adopting the above electrical connection method; and
the above each electronic component includes a Mini-LED.

In the above display panel in the embodiments of the present disclosure, the Mini-LED is connected with the contact electrodes in the driving backplane in a binding mode by adopting the above electrical connection method, so the connection performance between the Mini-LED and the contact electrodes is good.

The above driving backplane drives the Mini-LED, so that addressing control and individual driving of each pixel can be achieved, thereby achieving screen display.

Accordingly, the above Mini-LED may be a mini LED, and the above display panel may be applied to a large-size display screen or a display screen with a low resolution requirement.

Based on the same concept, the embodiments of the present disclosure further provide a display apparatus, including: the above backlight module and a liquid crystal display panel arranged on a light emitting side of the backlight module; or the above display apparatus includes the above display panel, that is, the display apparatus may also be an LED display apparatus. The display apparatus may be applied to any products or components with display functions such as a mobile phone, a tablet computer, a television, a monitor, a notebook computer, a digital photo frame, a navigator, etc. Since the principle of solving the above problem of the display apparatus is similar to the above backlight module (or display panel), the implementation of the display apparatus may refer to the implementation of the above backlight module (or display panel), and the repetition will not be repeated.

In the electrical connection method of the electronic components and the related apparatuses thereof provided by the embodiments of the present disclosure, the anti-oxidation protective film is formed on the contact electrodes, so that the contact electrodes can be prevented from being oxidized for a long time, it is ensured that the contact electrodes can be well connected with the binding material, the nickel-gold process can be omitted, and the process is simplified.

Although preferred embodiments of the present disclosure have been described, additional changes and modifications to these embodiments may occur to those skilled in the art once the basic inventive concepts are known. Therefore, the appended claims are intended to be construed to include the preferred embodiments and all changes and modifications that fall within the scope of the present disclosure.

Obviously, those skilled in the art can make various changes and modifications to the embodiments of the present disclosure without departing from the spirit and scope of the embodiments of the present disclosure. As such, provided that these modifications and variations of the embodiments of the present disclosure fall within the scope of the claims of the present disclosure and their equivalents, the present disclosure is also intended to cover such modifications and variations.

1. An electrical connection method of electronic components, comprising:
providing a driving backplane comprising a plurality of contact electrodes;
forming an anti-oxidation protective film on the contact electrodes;
coating the anti-oxidation protective film at positions corresponding to the contact electrodes with a binding material;
transferring a plurality of electronic components to positions of the contact electrodes; and
binding the electronic components each with a respective one of the contact electrodes;
wherein before completing the binding of the electronic components each to the respective one of the contact electrodes, the anti-oxidation protective film at the positions of the contact electrodes are removed.

2. The electrical connection method according to claim 1, wherein said forming the anti-oxidation protective film on the contact electrodes, comprises:
putting the driving backplane in an anti-oxidation protective solution, and soaking for 30-90 s.

3. The electrical connection method according to claim 2, wherein said putting the driving backplane in the anti-oxidation protective solution, comprises:
putting the driving backplane in a solution of benzotriazole.

4. The electrical connection method according to claim 1, wherein said coating the anti-oxidation protective film at positions corresponding to the contact electrodes with the binding material, comprises:
coating the anti-oxidation protective film with tin paste.

5. The electrical connection method according to claim 4, wherein said binding the electronic components each with a respective one of the contact electrodes, comprises:
binding the electronic components each with the respective one of the contact electrodes by adopting a reflow soldering process.

6. The electrical connection method according to claim 1, wherein the binding material is doped with a reactant for removing the anti-oxidation protective film; and
said binding the electronic components each with a respective one of the contact electrodes, comprises:
volatilizing a product of the reactant and the anti-oxidation protective film, and an excess reactant, in a process of binding the electronic components each with the respective one of the contact electrodes.

7. The electrical connection method according to claim 6, wherein the reactant comprises rosin resin or isophthalic acid.

8. The electrical connection method according to claim 1, wherein after forming the anti-oxidation protective film on the contact electrodes, within a set time before coating the anti-oxidation protective film at positions corresponding to the contact electrodes with the binding material, the method further comprises:
putting the driving backplane after forming the anti-oxidation protective film in a reactant for removing the anti-oxidation protective film, and soaking for 60-120 s.

9. The electrical connection method according to claim 8, wherein the reactant comprises isophthalic acid, ethyl alcohol or dilute acid.

10. (canceled)

11. A display panel, comprising:
a driving backplane, and
a plurality of electronic components arranged above the driving backplane,
wherein the electronic components are connected with contact electrodes in the driving backplane in a binding mode by adopting the electrical connection method according to claim 1; and
the electronic component comprise a mini-light emitting diode.

12. A display apparatus, comprising:
the backlight module according to claim 10, and
a liquid crystal display panel arranged on a light emitting side of the backlight module

13. A display apparatus, comprises the display panel according to claim 11.
